(19) United States
(12) Patent Application Publication
(10) Pub. No.: US 2026/0164689 A1
(43) Pub. Date: Jun. 11, 2026

(54) TRENCH-GATED SWITCH WITH TRENCH GATE WITHIN EPITAXIAL P-BODY LAYER

(71) Applicant: Pakal Technologies, Inc., SAN FRANCISCO, CA (US)

(72) Inventors: Vladimir Rodov, Seattle, WA (US); Paul M Moore, Hillsboro, CA (US)

(73) Assignee: Pakal Technologies, Inc., SAN FRANCISCO, CA (US)

(21) Appl. No.: 19/451,956

(22) Filed: Jan. 16, 2026

Related U.S. Application Data
(63) Continuation-in-part of application No. 18/808,080, filed on Aug. 19, 2024.
(60) Provisional application No. 63/536,403, filed on Sep. 2, 2023.

(51) Int. Cl. H10D 12/00; H10D 12/01; H10P 30/20

(52) U.S. Cl. CPC H10D 12/481; H10D 12/038; H10P 30/21

(57) ABSTRACT

In a vertical switch having various doped layers, such as npnp or npn layers, and an array of trenched gates, a p-body layer is formed over an n− drift layer. A portion of the p-body layer is inverted by the voltage on the gate to form an n-channel to turn the device on. The device is improved by forming the p-body by epitaxial growth, rather than by injection and diffusion. In this way, the distance between trenched gates can be more reliably selected to maximize current density and efficiency without any significant adverse effects due to variances in trench depth. Further, since the dopant concentration in the p-body layer is more reliably known, the depth of the trenches can be more easily selected to achieve a desired breakdown voltage at specified operating voltages.

### CROSS-REFERENCE TO RELATED APPLICATIONS

This application is a continuation-in-part of U.S. application Ser. No. 18/808,080, filed Aug. 19, 2024, which was based on provisional application Ser. No. 63/536,403, filed Sep. 2, 2023, by Vladimir Rodov et al., assigned to the present assignee and incorporated herein by reference.

### FIELD OF THE INVENTION

This invention relates to insulated trench gate power devices, such as vertical and lateral MOSFETs, vertical and lateral insulated gate bipolar transistors (IGBTs), vertical and lateral insulated gate turn-off (IGTO) devices, and other types of semiconductor devices that are generally used to switch high current/high voltage loads and, in particular, to a novel body region and gate trench structure that increases breakdown voltage, improves the control of dopant diffusion, increases yield, and improves performance.

### BACKGROUND

Applicant's U.S. Pat. No. 8,878,238, incorporated by reference, discloses a vertical power device which will be used as an example of one of many types of power devices that can benefit from the present invention. The power device from U.S. Pat. No. 8,878,238 will be described in detail, and the invention will later be described as a modification to such a device, and other insulated trench gate power devices, rather than repeating a detailed description of the prior art portion of the inventive structure.

Prior art FIG. 1 is a cross-sectional view of a small portion of a vertical power device 10 described in U.S. Pat. No. 8,878,238 that can benefit from the present invention. Although FIG. 1 just shows an edge portion of the cellular power device 10, the invention applies to all areas within the cellular array.

Three cells are shown having vertical gates 143, consisting of doped polysilicon, formed in insulated trenches 141A. Trench 141B is for a polysilicon connection to all the gates 143 and may not be considered a cell. A 2-dimensional array of the cells forming strips or a rectangular mesh may be formed in a common, lightly-doped p-well 107 (acting as a p-base), and the cells are connected in parallel.

Trenched gates are used because they take up very little silicon real estate, and vertical devices can typically have a breakdown voltage that is higher than a lateral device (horizontal gates on top).

N+ regions 129, forming sources, surround some or all of the gates 143 and are contacted by a top, metal cathode electrode 127 having a cathode terminal 101. The n+ regions 129 may be formed by implantation or by other known dopant introduction methods.

The vertical gates 143 are insulated from the p-well 107 by an oxide layer 145. The gates 143 are connected together outside the plane of the drawing and are coupled to a gate voltage via a metal gate electrode 109 (which may be a gate pad coupled to a lead of the die) directly contacting the polysilicon in the trench 141B. A patterned dielectric layer 119 insulates the gate electrode 109 from the p-well 107 and insulates the gates 143 from the cathode electrode 127.

Guard rings 113 near the edge of the die reduce field crowding for increasing the breakdown voltage. The guard rings 113 are contacted by metal 161 and 163, which are insulated from the n− drift layer 106 by field oxide 117.

A vertical npnp semiconductor layered structure is formed. There is a bipolar pnp transistor formed by a p+ substrate 104, an epitaxially grown n− drift layer 106 (acting as an n− base), and the p− well 107. There is also a bipolar npn transistor formed by the n+ regions 129, the p-well 107, and the n− drift layer 106. An n-type buffer layer 105, with a dopant concentration higher than that of the n− drift layer 106, reduces the injection of holes into the n− drift layer 106 from the p+ substrate 104 when the device is conducting. A bottom anode electrode 103, having an anode terminal 102, contacts the substrate 104, and the top cathode electrode 127, having a cathode terminal 101, contacts the n+ regions 129 and also contacts the p-well 107 at selected locations. The p-well 107 surrounds the gate structure, and the n− drift layer 106 extends to the surface around the p-well 107.

When the anode electrode 103 is forward biased with respect to the cathode electrode 127, but without a sufficiently positive gate bias, there is no current flow, since there is a reverse biased vertical pn junction impeding the injection of electrons from the source regions into the n-base, and the cathode-base pn junction is heavily shunted.

In this present disclosure, the inventors explain their non-obvious improved understanding of the detailed operation of the device. Simulations and actual products proved the previous devices worked. In the past, the inventors believed that the device of FIG. 1 only turned on when the product of the betas (gains) of the pnp and npn transistors was greater than one (i.e., there is regeneration activity) due to an effective narrowing of the base width of the npn transistor when the gate was biased on and an inversion layer was formed around the trench. Now that the inventors better understand the non-obvious operation of the device, certain additional improvements of the device structure can be obtained, explained later.

According to the inventors' previous understanding, when the gate 143 is sufficiently biased with a positive voltage (relative to the n+ regions 129), such as 2-5 volts, an inversion layer is formed around the gate 143, and electrons from the n+ regions 129 become the majority carriers along the gate sidewalls and below the bottom of the trenches in the inversion layer. At a certain level of majority carrier accumulation, breakover occurs, when holes are injected into the lightly doped n− drift layer 106 and electrons are injected into the p-well 107 to fully turn on the device. Accordingly, the gate bias initiates the turn-on, and the full turn-on (due to regenerative action) occurs when there is current flow through the npn transistor as well as current flow through the pnp transistor.

When the gate bias is taken to zero, such as the gate electrode 109 being shorted to the cathode electrode 127, or taken negative, the power device 10 turns off.

The device 10 is intended to be used as a high voltage/high current switch with very low voltage drop when on. The maximum voltage for proper operation is specified in a data sheet for the device 10.

The device 10 is cellular (all cells are connected in parallel), the trenches are filled with doped polysilicon, and all the gates are connected together to a single driver.

FIG. 2 illustrates the net dopant concentration vs. depth into the wafer prior to the formation of the n+ regions 129. Note how the p-dopants in the p-well 107 and the n-dopants in the drift layer 106 have cancelled each other out to cause a low net doping area near the pn junction. This is due to the long diffusion time of the p-dopants, which also causes the n-dopants to diffuse upward. This results in a need to precisely control the gate trench depth, since the optimal trench depth and the optimal spacing between trenches depend on the dopant concentration near the bottom of the trenches, and the dopant concentration changes with depth.

Achieving a consistent breakdown voltage is difficult, since the depletion region in the p-well 107 must not reach the bottom of the trenches, and the depletion region for a given reverse voltage depends on the dopant concentration.

FIG. 3 illustrates the net doping concentration after the n-dopants have been implanted in the top of the p-well 107 and then diffused to form the n+ regions 129 (sources). After the diffusions, the p-well 107 has an undesirable varying dopant concentration.

FIG. 4 shows the net doping concentration near a generic pn junction where the n and p implanted dopants have a long diffusion time. Note how the diffused dopants cancel each other out (overlap) for a wide region near the pn junction. In contrast, FIG. 5 shows the same silicon but with a much shorter diffusion time, resulting in the n and p regions being more defined with more uniform net dopant concentrations. The dopant profile of FIG. 5 is preferred over the dopant profile of FIG. 4. However, the profile of FIG. 5 may not be achievable with large implanted p-wells.

As discussed, the net doping in the p-well 107 changes throughout its depth, and the depth of the trenches is critical to certain performance parameters. The maximum extraction of electrons from the inversion layer surrounding the trenches can only be achieved when the distances between the trenches are less than a specific amount related to a Debye length, and the Debye length is related to the net doping. Since the net doping in the p-well changes with depth, such required distances are dependent on the depth of the trenches, and the tolerances for the depth of the trenches and the net doping vs. depth are high. Therefore, optimal distances between trenches are not achievable, and current density cannot be maximized. Further, as discussed above, achieving a consistent breakdown voltage is difficult, reducing yields. Other drawbacks also exist from the variable doping concentration in the p-well 107.

What is needed is a new design where the depths of the trenches within the p-well are not critical to performance, resulting in higher yields.

### SUMMARY

Instead of a p-body (or p-well) being formed in an n− drift layer in a switching device by implantation and dopant diffusion, the p-body is formed by p-doping during epitaxial layer growth over the n− drift layer. This creates a fairly uniformly doped and defined p-body layer. After the epitaxial p-body layer is formed, p-dopants can be implanted to a shallow depth through the top of the p-body layer and quickly diffused to form a relatively thin layer of higher p-concentration material near the “top” of the inversion channels created by the trenched gates.

N-dopants are then implanted into the top p-layer and quickly diffused (since the layer is thin) to form the n+ source regions.

Next, the trenches for the gates are formed. The trenches in the active area of the device terminate in the p-body layer, and the trenches in the termination area extend down into the n-drift layer. A thin oxide is then formed on the trench walls, and the insulated trenches are filled with doped polysilicon to form gates (or gate electrodes). There are no n+ source regions or implanted top p-layer in the termination area since it is intended to be inactive and only serves to spread the voltage potential between the active area and the edges of the die to improve the breakdown voltage.

Based on the inventors' improved understanding of the operation of the device, the depth of the trenches can be much shallower (compared to the epitaxial p-body thickness), since the variable npn base width is not critical to the operation of the device, and the thickness of the epitaxial p-body can be much greater to separate the bottom of the trenches from the pn junction and increase the breakdown voltage. The spacing of the trenches can also be optimized for maximum current density.

The remaining features of the switching device are then formed, which may be similar to the prior art.

The above-described techniques form an npnp layered IGTO device that is an improvement over the IGTO device of FIG. 1.

In addition to increasing the breakdown voltage by increasing the separation of the trench from the pn junction, the p-dopant concentration in the epitaxial p-body layer can be increased to increase the breakdown voltage since there is less depletion under the trenches when the device is off or when there is a reverse voltage condition. In contrast, if the p-dopants were implanted and diffused, there would be a significant gradient of the net p-type dopant concentration with depth into the wafer, causing the p-type doping to be too high near the top surface and too low near the bottom of the p-body. Thus, in the prior art, the depth and spacing of the trenches would be critical for proper operation, and yields would suffer.

By forming a shallow, upper enhanced p-layer by implantation and diffusion, the p-layer directly under the n+ sources can have the optimal net p-type concentration for achieving the desired gate turn-on voltage while not affecting the breakdown voltage.

Other advantages exist.

The device power electrodes may be on opposite sides of the die (vertical) or on the same side of the die (lateral).

Other embodiments are disclosed.

### BRIEF DESCRIPTION OF THE DRAWINGS

FIG. 1 is copied from Applicant's U.S. Pat. No. 8,878,238 and is a cross-section of an edge of a vertical switch having an array of insulated trench gates connected in parallel.

FIG. 2 is a graph (profile) of net dopant concentration vs. wafer depth after the p-well of FIG. 1 is formed using ion implantation and a long diffusion time.

FIG. 3 illustrates the dopant profile after the n+ source regions of FIG. 1 are formed.

FIG. 4 is generic and illustrates how a long-time diffusion of dopants creates a gradual gradient in n or p net doping concentration due to dopant overlap, which prevents optimizing the characteristics of regions in a power switch.

FIG. 5 is generic and illustrates the benefits of short-time diffusion of dopants, where the doped regions are better defined, enabling the regions to have more optimal and predictable characteristics.

FIG. 6 illustrates one embodiment of the invention and shows the formation of an epitaxially grown p-body layer over the n− drift layer for a device ultimately similar to that of FIG. 1.

FIG. 7 illustrates the implantation and short-time diffusion of p-dopants in the top surface of the epitaxially grown p-body layer of FIG. 6 to form a higher concentration p-layer abutting the trenched gates to control the gate turn-on voltage, while customizing the epitaxially grown p-body layer for optimizing breakdown voltage and on-voltage.

FIG. 8 illustrates the use of the present invention in a device similar to that of FIG. 1.

FIG. 9 illustrates the net dopant profile of the device of FIG. 8 next to a gate trench in the active area, showing well-defined and optimized doped regions for customizing turn-on voltage, breakdown voltage, and on-voltage (voltage drop).

FIG. 10 is similar to FIG. 8 but shows how the epitaxial p-body can be made much thicker for increasing the breakdown voltage without significantly affecting the other parameters of the device.

Elements that are the same or equivalent in the various figures may be labeled with the same numeral.

### DETAILED DESCRIPTION

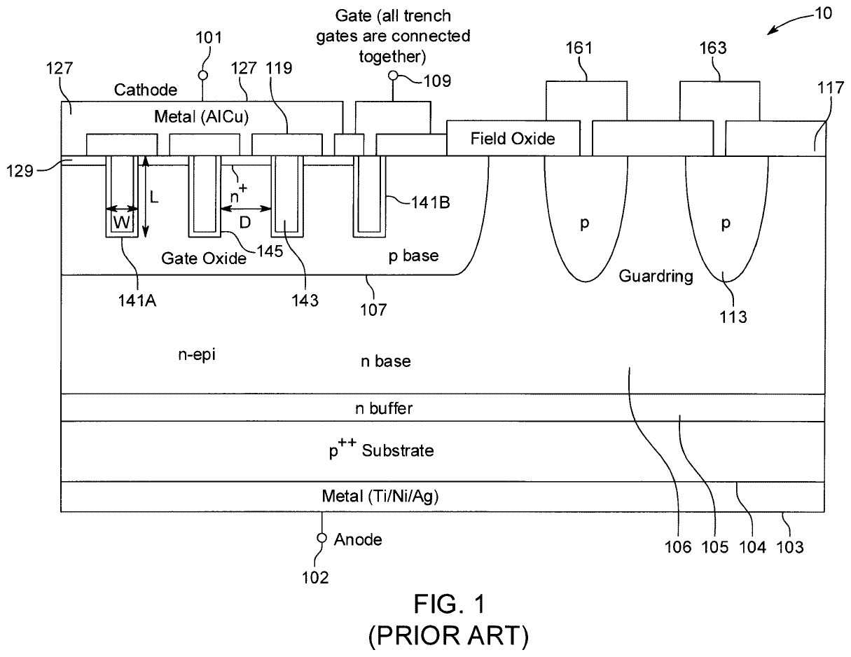

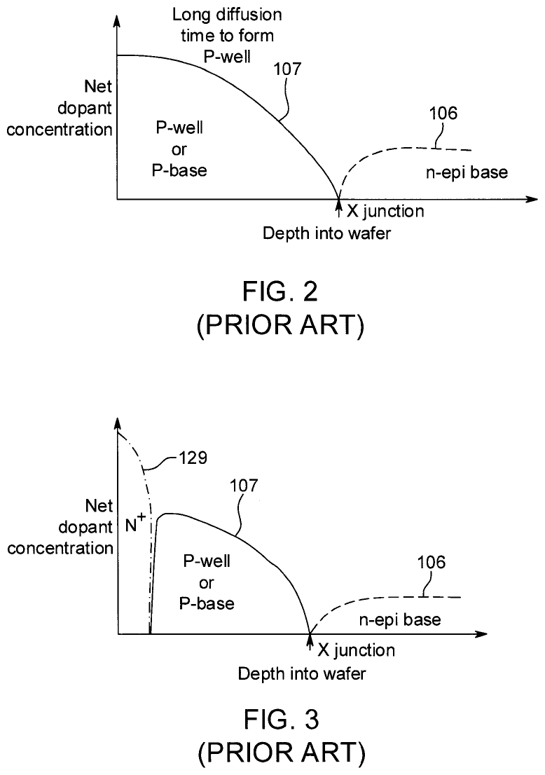

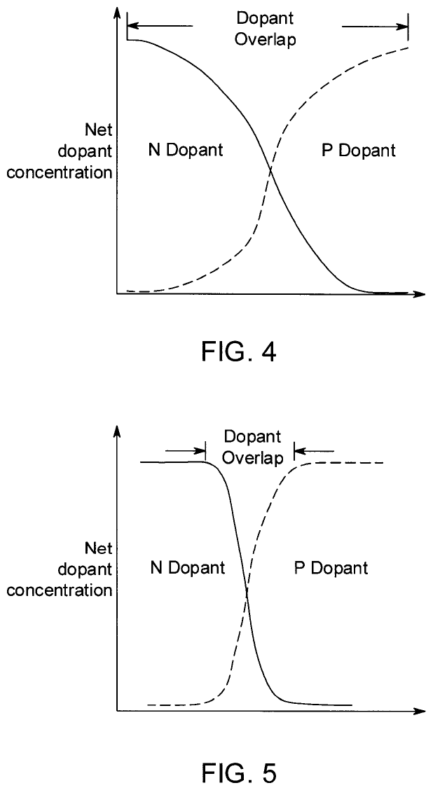

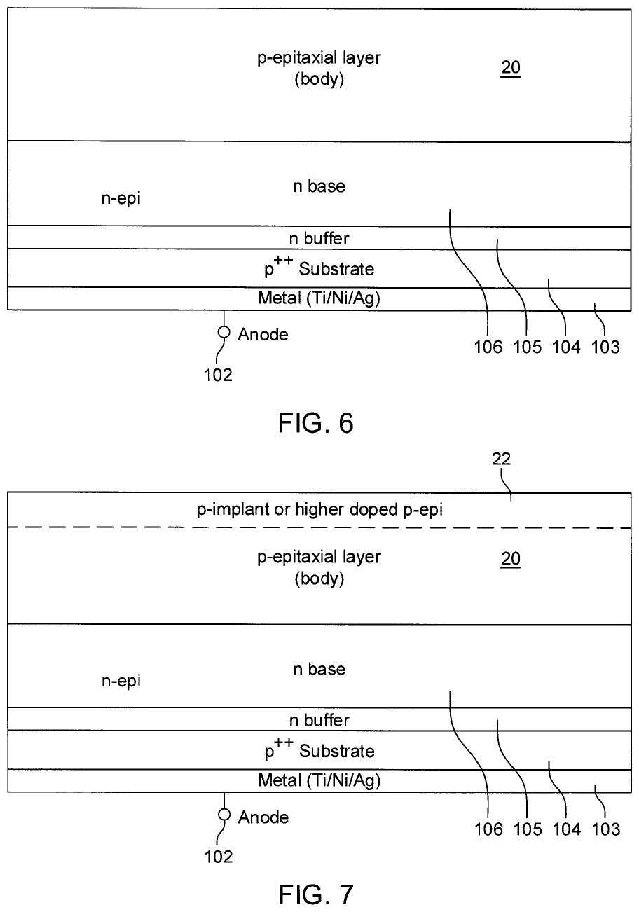

FIG. 6 is a cross-sectional view of a portion of an Insulated Gate Turn Off Device during fabrication. The layers 103-106 may be the same as in FIG. 1. Instead of a p-body or p-well being formed by ion implantation and diffusion into the epitaxial n− drift layer 106, a new p− epitaxial layer is formed which is the p-body 20. If the wafer is silicon, a silicon epitaxial layer is formed while introducing p-dopants into the growth chamber. Epitaxial growth temperature is on the order of 1000 degrees C. and the growth rate is typically between 1-10 microns per minute. In one embodiment, the p-body 20 has a thickness less than 20 microns.

In contrast, for a deep implant and diffusion, the required diffusion time to form a p-body may be up to 10 hours at 1000 degrees C. Therefore, the required time to form the p-body 20 by epitaxial growth is much less than the time needed for diffusion of the p-dopants in the n− drift layer 106. As a result, there is much less diffusion of n-dopants from the n− drift layer 106 into the p-body 20 and much less diffusion of p-dopants into the n− drift layer 106, resulting in more well-defined regions and more uniform dopant distribution.

The thickness of the various layers in FIG. 6 depends on the requirements of the device, and such required thicknesses can be determined by simulation.

FIG. 7 illustrates forming a higher doped p-layer 22 (an Enhanced Threshold body layer (ETV)) in the top portion of the p-body 20. This may be done by a shallow ion implant of p-dopants into the p-body 20 followed by a short-time diffusion. Alternatively, during the epitaxial growth process for forming the p-body 20, the p-dopant gas may be increased to increase the p-dopant concentration in the p-layer 22 or to vary the dopant concentration in any way.

This enhanced p-layer 22 affects the turn-on gate voltage Vt of the device, where an increased dopant concentration raises the Vt. The dopant concentration in the p-body 20 is therefore independently controlled to modify a breakdown voltage of the device. For example, a very low dopant concentration in the p-body 20 would result in a depletion region reaching up to the gate trenches and causing a breakdown through the gate oxide. However, such a low dopant concentration also allows for a larger inversion channel when the device is turned on, allowing a higher current density. The p-body 20 next to a gate trench may be inverted at a low gate voltage prior to the device turning on, since the p-layer 22 has not been inverted. An increase in gate voltage then turns on the device by inverting the p-layer 22. So, the p-body 20 dopant concentration can be adjusted to independently control certain device characteristics, while the p-layer 22 can be controlled for achieving other device characteristics.

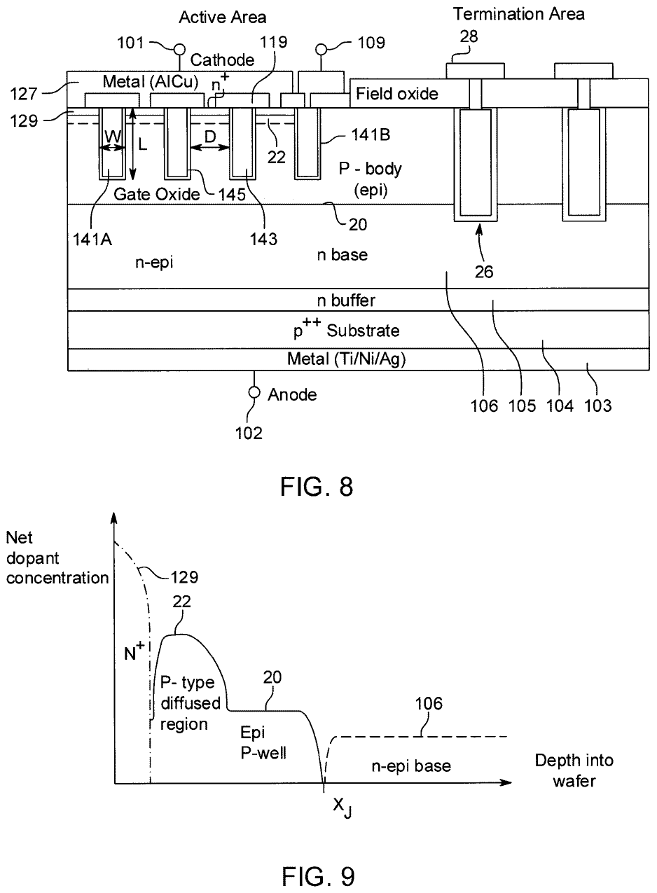

In FIG. 8, n-dopants are implanted in the surface and diffused for a short time to form the n+ source regions 129.

Then, an array of trenches is formed in the active area that terminate in the p-body 20. The trenches are oxidized for form a thin gate oxide 145, then filled with doped polysilicon to form the gates 143.

The various dielectric regions are formed and metal electrodes are formed as discussed with respect to FIG. 1.

To assure electron extraction from the inversion layer along the sides of the gates, the doping concentration in the epitaxial portion of the p-body 20 must satisfy the relation with the distance D (FIG. 8) between the gate trenches in accordance with the following equations:

$$D < 4 {λ}_{D} ,$$

where λ_{D} is the Debye length in the lightly doped p-body 20. The Debye length is the distance in a semiconductor layer over which the charge in the inversion layer of a MOS-gated structure is reduced by 1/e, determined by the following equation:

$${λ}_{D} = \sqrt{\frac{{ε}_{0} {k}_{B} {T}_{e}}{{n}_{e} {q}_{e}^{2}}}$$

where ε₀ is the dielectric constant of the silicon forming the p-body 20 near the bottom of the trenches
k_{B} is the Boltzmann constant
Tₑ is the absolute temperature in Kelvinqₑ is the elementary charge, and nₑ is the net dopant concentration of p-dopants in the p-body 20.

As an important consequence of the above equations, we can observe that when the net p-dopant concentration in the p-body 20 is constant (as in the case with an epitaxial p-body), the position of the bottom of the gate trench is not important if it is inside the p-body. This fact leads to a much more reliable gate trench process.

Since the Debye length can be easily controlled with the epi p-body 20 and is relatively constant throughout the p-body 20 depth, the distance D in order to meet the equation requirement is easily achieved, allowing a higher density of trenches and a higher current density. Yield is increased also.

Further, with the prior art fabrication processes, the Applicant was also concerned with the depth of the trenches being sufficiently deep to achieve a specified turn-on voltage, while the depth had to be a certain distance from the bottom of the p-body to avoid breakdown of the gate oxide at the specified operating voltages. With the uniform doping of the p-body 20 in the present invention, it is easier to ensure that the turn-on voltage is at or below the specified value, since there is no issue with a changing dopant concentration in the p-body. Further, the required depth of the trenches to avoid gate oxide breakdown can be easily determined due to the predictability of the dopant concentration of the p-body 20 near the bottom of the trenches.

Based on the inventors' more in-depth knowledge of the operation of the device, the trench depth can have a broad range without affecting performance. In one example, the trench depth is 3 microns while the depth of the p-body 20 can be 200 microns. The thicker p-body 20 increases the breakdown voltage since the maximum depletion region in the p-body 20 will not reach up to the trench bottom. Therefore, there will be no gate oxide breakdown.

The regenerative mechanism in the IGTO device is different from an ordinary npnp thyristor mainly because of the difference between the injection mechanisms of a pn junction and the extraction of electrons from an inversion layer (as takes place in the IGTO device).

In the IGTO device, the gate trench protrudes through the n+ regions 129, through the enhanced (ETV) p-layer 22, and terminates in the p-body 20.

A positive gate bias above a threshold will create an inversion layer of electrons around the gate oxide of the trench gate.

If the distance between the gate trenches in the p-body 20 is smaller than 4 Debye length, the available space charge between the gate trenches will not be able to support the total charge of electrons in the inversion layer and the excess of electrons will be expelled from the inversion layer through the sides of the gate trenches into the p-body 20.

This is the mechanism of an induced injection.

We can observe that an induced injector can inject only electrons, and this is a major difference between its functioning in the IGTO device and of a pn junction functioning in thyristors.

The injection of electrons (i.e., the extraction of electrons from the inversion layer) in the p-body 20 is an introduction of electric charge in the p-body 20. Any charge introduced in a conductive area will be promptly expelled via the Maxwell Relaxation mechanism (also called the Dielectric Relaxation mechanism).

This means that induced charges will end up in a very short time on the border of the pn central junction.

Because the p-body 20 receives this influx of electrons, the local charge distribution temporarily departs from equilibrium. However, due to the efficient action of the Maxwell Relaxation mechanism, these excess electrons are rapidly redistributed or neutralized, ensuring that the p-body 20 does not accumulate persistent space charge. This rapid neutralization is essential for the device's stable operation and distinguishes the IGTO device behavior from that of conventional thyristors.

Continuity of current produced by the above process will start forward biasing of the anode junction and, in response, the anode junction will be forward bias and start injecting holes.

This will begin the regenerative process that will end in restoration of quasi neutrality of the whole system. When the quasi neutrality of the whole system is restored at a normal forward bias current, the IGTO device will look like a PIN Diode with very low forward voltage (Vf), not unlike a thyristor.

The Maxwell Relaxation mechanism therefore fulfills the role of transport mechanism in the base of bipolar pnpn thyristors.

The very crucial property of the Maxwell Relaxation mechanism is its practical independence of the process from the thickness of the p-body 20.

This allows:
a) Freedom of moving the trench in the p-body 20 and
b) Solving very important problems with reliability of IGTO devices.

FIG. 8 shows the termination area on the right side for spreading the voltage potential for increasing the breakdown voltage. In the termination area, there is no enhanced p-layer 22 since the area was masked during the implantation process. In the termination area, deep insulated trenches 26 are formed followed by the trenches 26 being filled with doped polysilicon. The conductive trench areas may be floating or connected to a fixed voltage via metal contacts 28. The trenches 26 form rings that surround the active area. The termination area is inactive since there are no source regions formed in the termination area.

The IGTO device of FIG. 8 has more controllable characteristics compared to the device of FIG. 1, is faster to fabricate, and has more predictable and repeatable characteristics from lot to lot.

FIG. 9 shows a dopant profile of the device of FIG. 8 along the gate trenches. Note how the transitions between regions are more highly defined compared to the profile of FIG. 3.

The shorter time of fabrication of the p-body 20 results in less diffusion of all doped layers that were previously formed, including layers 105 and 106 and the p-type substrate 104. Therefore, the net dopant concentrations are retained, and performance characteristics of all the layers are retained.

By proper selection of the dopant concentration and sizes of the p-body 20 and p-layer 22, the gate trench depths and spacings can be optimized. For example, using the inventive process, the effective p-dopant concentration in the p-layer 22 and p-body 20 can be increased to increase the hole current, allowing a smaller trench spacing and higher current density for the device. This change can be made without reducing the breakdown voltage.

Further, tolerances in the various layers' thicknesses can be reduced since there is less diffusion, resulting in more repeatable performance from lot to lot and higher yields.

Further, the p-body 20 doping concentration and the characteristics of the n− drift layer 106 affect the breakdown voltage in the termination area. So these characteristics can be optimized for breakdown voltage, while the p-layer 22 in the active area can be optimized for turn-on voltage.

In one process embodiment, the substrate 104 is ground down, followed by an n-dopant implant for the n-buffer layer 105 and a p-dopant implant to form the p+ bottom layer. A metallization step is then conducted.

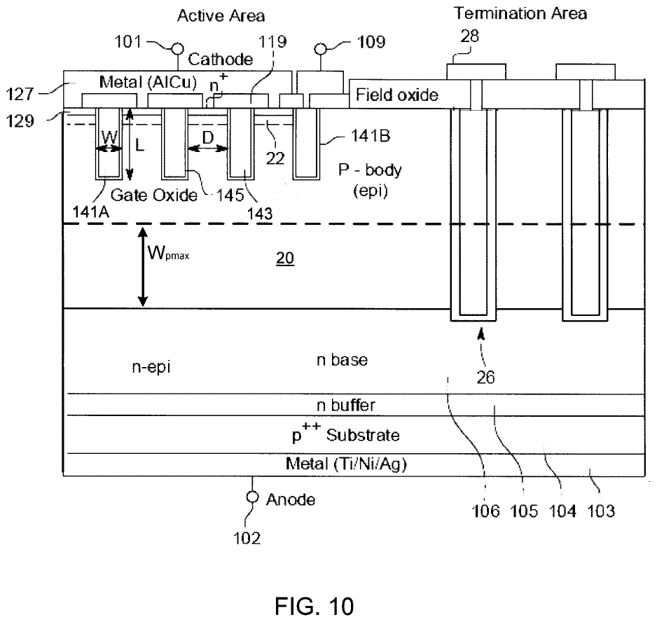

FIG. 10 illustrates how the p-body 20 depth can be any suitable depth to support a specified voltage without significantly affecting other parameters of the device. The maximum depletion region Wpmax (with a maximum reverse bias) into the p-body 20 is shown, which is below the bottom of the trench.

When reverse engineering completed devices using a scanning electron microscope, whether a p-body layer is formed by diffusion or epitaxially can be easily determined by techniques used to determine doping concentrations. The epitaxial layer will be much more uniform than a layer that has been formed using implantation and diffusion. Therefore, there are always physical differences between the two types of layers.

The gate trenches in the active area may be formed in strips, in squares, in hexagons, or other shapes to form a 2-dimentional array of cells connected in parallel to create a device having a wide range of current capacities.

A lateral device may be formed by providing a highly doped buried layer and a deep sinker to provide both electrodes on top.

The conductivity type of the various layers can be reversed to form a pnpn device.

Various features disclosed may be combined to achieve a desired result.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A method of forming a semiconductor, insulated trench gate switching device comprising:
forming an n-type first semiconductor layer over a substrate to form a drift layer;
epitaxially growing a p-type second semiconductor layer on the first semiconductor layer to form a first body layer, the second semiconductor layer having a first dopant concentration;
forming an n-type third semiconductor layer over the third semiconductor layer to form source regions;
forming an array of first trenches terminating within the second semiconductor layer, the trenches having sidewalls;
forming a dielectric layer on the sidewalls;
depositing a first conductive material in the trenches abutting the dielectric layer to form vertical gates;
forming a first electrode contacting the source regions; and
forming a second electrode contacting the substrate;
wherein a top portion of the gates abuts the third semiconductor layer, and a bottom portion of the gates abuts the first body layer, such that a threshold voltage applied to the gates inverts portions of the first body layer to form a vertical conductive path for current flow.

2. The method of claim 1,
wherein a doping concentration in the first body layer satisfies the relation with a distance D between the first trenches in accordance with the following equations:
$$D < 4 {λ}_{D} ,$$
where λ_{D} is the Debye length in the first body layer, wherein the Debye length is the distance in the first body layer over which a charge in the inversion layer surrounding the first trenches when the device is turned on is reduced by 1/e, determined by the following equation:
$${λ}_{D} = \sqrt{\frac{{ε}_{0} {k}_{B} {T}_{e}}{{n}_{e} {q}_{e}^{2}}}$$
where ε₀ is the dielectric constant of the first body layer
k_{B} is the Boltzmann constant
Tₑ is the absolute temperature in Kelvinqₑ is the elementary charge, and nₑ is the net dopant concentration of p-dopants in the p-body.

3. The method of claim 1 further comprising forming an enhanced body layer by implanting p-type dopants into a surface of the first body layer and diffusing the dopants.

4. The method of claim 3 wherein forming the enhanced body layer comprises varying a dopant concentration while epitaxially growing the second semiconductor layer.

5. The method of claim 1 wherein the substrate is p-type.

6. The method of claim 1 wherein the method forms a npnp layered device that is switched on and off by applying voltage to the vertical gates.

7. The method of claim 1 wherein a distance between a bottom of the first trenches and a top of the first semiconductor layer is greater than a maximum depletion region that forms in the second semiconductor layer at operating voltages.

8. A semiconductor, insulated trench gate switching device comprising:
an n-type first semiconductor layer over a substrate, the first semiconductor layer being a drift layer;
an epitaxially grown p-type second semiconductor layer on the first semiconductor layer, the second semiconductor layer being a first body layer, the second semiconductor layer having a first dopant concentration;
a p-type third semiconductor layer over the second semiconductor layer, the third semiconductor layer being an enhanced body layer, the third semiconductor layer having a second dopant concentration higher than the first dopant concentration;
an n-type fourth semiconductor layer over the third semiconductor layer, the fourth semiconductor layer being source regions;
an array of first trenches terminating within the second semiconductor, the trenches having sidewalls;
a dielectric layer on the sidewalls;
a first conductive material in the trenches abutting the dielectric layer forming vertical gates;
a first electrode contacting the source regions; and
a second electrode contacting the substrate,
wherein a top portion of the gates abuts the enhanced body layer, and a bottom portion of the gates abuts the first body layer, such that a threshold voltage applied to the gates inverts the first body layer and the enhanced body layer to form a vertical conductive path for current flow.

9. The device of claim 8,
wherein a doping concentration in the first body layer satisfies the relation with a distance D between the first trenches in accordance with the following equations:
$$D < 4 {λ}_{D} ,$$
where λ_{D} is the Debye length in the first body layer, wherein the Debye length is the distance in the first body layer over which a charge in the inversion layer surrounding the first trenches when the device is turned on is reduced by 1/e, determined by the following equation:
$${λ}_{D} = \sqrt{\frac{{ε}_{0} {k}_{B} {T}_{e}}{{n}_{e} {q}_{e}^{2}}}$$
where ε₀ is the dielectric constant of the first body layer
k_{B} is the Boltzmann constant
Tₑ is the absolute temperature in Kelvinqₑ is the elementary charge, and nₑ is the net dopant concentration of p-dopants in the p-body.

10. The device of claim 8 wherein the enhance body layer is formed by implanting p-type dopants into a surface of the first body layer and diffusing the dopants.

11. The device of claim 8 wherein the enhance body layer is formed by varying a dopant concentration while epitaxially growing the second semiconductor layer.

12. The device of claim 8 wherein the substrate is of the p-type.

13. The device of claim 8 wherein the device is a npnp layered device that is switched on and off by applying voltage to the gates.

14. The device of claim 8 wherein a distance between a bottom of the first trenches and a top of the first semiconductor layer is greater than a maximum depletion region that forms in the second semiconductor layer at operating voltages.
